(19) United States
(12) Patent Application Publication
(10) Pub. No.: US 2026/0331422 A1
(43) Pub. Date: Oct. 22, 2026

(54) PLASMA PROCESSING APPARATUS

(71) Applicant: Tokyo Electron Limited, Tokyo (JP)

(72) Inventors: Nozomu NAGASHIMA, Miyagi (JP); Kunihiko YAMAGATA, Miyagi (JP)

(73) Assignee: Tokyo Electron Limited, Tokyo (JP)

(21) Appl. No.: 19/695,877

(22) Filed: Jun. 2, 2026

Related U.S. Application Data
(63) Continuation of application No. PCT/JP2023/044917, filed on Dec. 14, 2023.

(51) Int. Cl. H01J 37/32; H01F 27/28

(52) U.S. Cl. CPC H01J 37/3211; H01F 27/28; H01J 37/32183; H01J 2237/334

(57) ABSTRACT

A plasma processing apparatus includes a chamber, a substrate support, a load, a transmitting coil, a receiving coil, a rectifying and smoothing circuit, an energy storage, a power supply line, a radio frequency power supply, and a ground pipe. The substrate support and the load are in the chamber. The transmitting coil and the receiving coil are coupled by electromagnetic induction. The rectifying and smoothing circuit is configured to convert power from the receiving coil into DC power. The energy storage is connected between the rectifying and smoothing circuit and the load. The radio frequency power supply is configured to supply radio frequency power via the power supply line. The ground pipe extends through the inside of the receiving coil and the inside of the transmitting coil. The power supply line extends through the ground pipe outside the chamber.

### CROSS-REFERENCE TO RELATED APPLICATIONS

This application is a continuation application of PCT Application No. PCT/JP2023/044917, filed on Dec. 14, 2023. The entire contents of the above listed PCT and priority applications are incorporated herein by reference.

### BACKGROUND

### Field

Example embodiments of the present disclosure relate to a plasma processing apparatus.

### Description of the Related Art

A plasma processing apparatus is used in plasma processing. The plasma processing apparatus includes a chamber and a substrate support (stage) disposed in the chamber. The substrate support has a base (lower electrode) and an electrostatic chuck that holds a substrate. Inside the electrostatic chuck, a temperature adjusting element (for example, a heater) for adjusting the temperature of the substrate is located. In addition, between the temperature adjusting element and a power supply for the temperature adjusting element, a filter is provided that attenuates or blocks radio frequency noise entering on lines such as power supply lines and/or signal lines from radio frequency electrodes and/or other electrical members in the chamber. One type of such a plasma processing apparatus is described in Japanese Unexamined Patent Publication No. 2015-173027.

### SUMMARY

In one example embodiment, a plasma processing apparatus is provided. The plasma processing apparatus includes a plasma processing chamber, a substrate support, a load, a transmitting coil, a receiving coil, a rectifying and smoothing circuit, an energy storage, a radio frequency power supply line, a radio frequency power supply, and a ground pipe. The substrate support is in the plasma processing chamber. The load is in the plasma processing chamber or in the substrate support. The receiving coil is configured to receive power from the transmitting coil by electromagnetic induction coupling. The rectifying and smoothing circuit is configured to convert power from the receiving coil into DC power. The energy storage is electrically connected between the rectifying and smoothing circuit and the load. The radio frequency power supply is configured to generate radio frequency power to be supplied into the plasma processing chamber via the radio frequency power supply line. The ground pipe extends through the inside of the receiving coil and the inside of the transmitting coil, and is configured to electrically couple to ground. The radio frequency power supply line extends through the ground pipe outside the plasma processing chamber.

### BRIEF DESCRIPTION OF THE DRAWINGS

FIG. 1 is a diagram for explaining a configuration example of a plasma processing system.

FIG. 2 is a diagram for explaining a configuration example of a capacitively coupled plasma processing apparatus.

FIG. 3 is a diagram schematically illustrating a plasma processing apparatus according to one example embodiment.

FIG. 4 is a diagram schematically illustrating a plasma processing apparatus according to another example embodiment.

FIG. 5 is a diagram schematically illustrating a plasma processing apparatus according to yet another example embodiment.

FIG. 6 is a diagram schematically illustrating a plasma processing apparatus according to yet another example embodiment.

FIG. 7 is a diagram schematically illustrating a plasma processing apparatus according to yet another example embodiment.

FIG. 8 is a diagram illustrating a power transmitter according to one example embodiment.

FIG. 9 is a diagram illustrating a transmitting coil module and a receiving coil module according to one example embodiment.

FIG. 10 is a diagram illustrating a transmitting coil module and a receiving coil module according to one example embodiment.

FIG. 11 is a diagram illustrating a transmitting coil module and a receiving coil module according to one example embodiment.

FIG. 12 is a graph illustrating impedance characteristics of a receiving coil module according to one example embodiment.

FIG. 13 is a diagram illustrating an RF filter according to one example embodiment.

FIG. 14 is a diagram illustrating a rectifying and smoothing circuit according to one example embodiment.

FIG. 15 is a diagram illustrating an RF filter according to one example embodiment.

FIG. 16 is a diagram illustrating a communication device of a power transmitter and a communication device of a rectifying and smoothing circuit according to one example embodiment.

FIG. 17 is a diagram schematically illustrating a plasma processing apparatus according to yet another example embodiment.

FIG. 18 is a diagram schematically illustrating a plasma processing apparatus according to yet another example embodiment.

FIG. 19 is a diagram illustrating a communication device of a power transmitter and a communication device of a rectifying and smoothing circuit according to another example embodiment.

FIG. 20 is a diagram schematically illustrating a plasma processing apparatus according to yet another example embodiment.

FIG. 21 is a diagram schematically illustrating a plasma processing apparatus according to yet another example embodiment.

FIG. 22 is a diagram schematically illustrating a plasma processing apparatus according to yet another example embodiment.

Each of FIG. 23A and FIG. 23B is a diagram illustrating an energy storage according to one example embodiment.

FIG. 24 is a diagram illustrating a voltage control converter according to one example embodiment.

FIG. 25 is a diagram illustrating a constant voltage controller according to one example embodiment.

FIG. 26 is a diagram illustrating a constant voltage controller according to another example embodiment.

FIG. 27 is a diagram schematically illustrating a plasma processing apparatus according to yet another example embodiment.

FIG. 28 is a diagram illustrating a transmitting coil module and a receiving coil module in a plasma processing apparatus according to yet another example embodiment.

FIG. 29 is a diagram illustrating a transmitting coil module and a receiving coil module in a plasma processing apparatus according to yet another example embodiment.

FIG. 30 is a diagram illustrating a transmitting coil module and a receiving coil module in a plasma processing apparatus according to yet another example embodiment.

FIG. 31 is a diagram schematically illustrating a plasma processing apparatus according to yet another example embodiment.

FIG. 32 is a diagram illustrating a transmitting coil module and a receiving coil module in a plasma processing apparatus according to yet another example embodiment.

### DETAILED DESCRIPTION

Hereinafter, various example embodiments will be described in detail with reference to the drawings. In the drawings, the same or equivalent portions are denoted by the same reference signs.

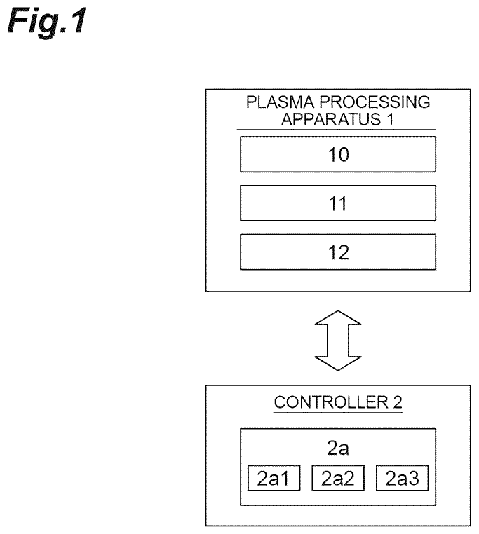

FIG. 1 illustrates an example configuration of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below, and the gas outlet is connected to a gas exhaust system 40 described below. The substrate support 11 is disposed in the plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, an AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, a part or all of the controller 2 may be incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads the program from the storage 2a2 to execute the program. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 may communicate with the plasma processing apparatus 1 via a communication line, such as a local area network (LAN).

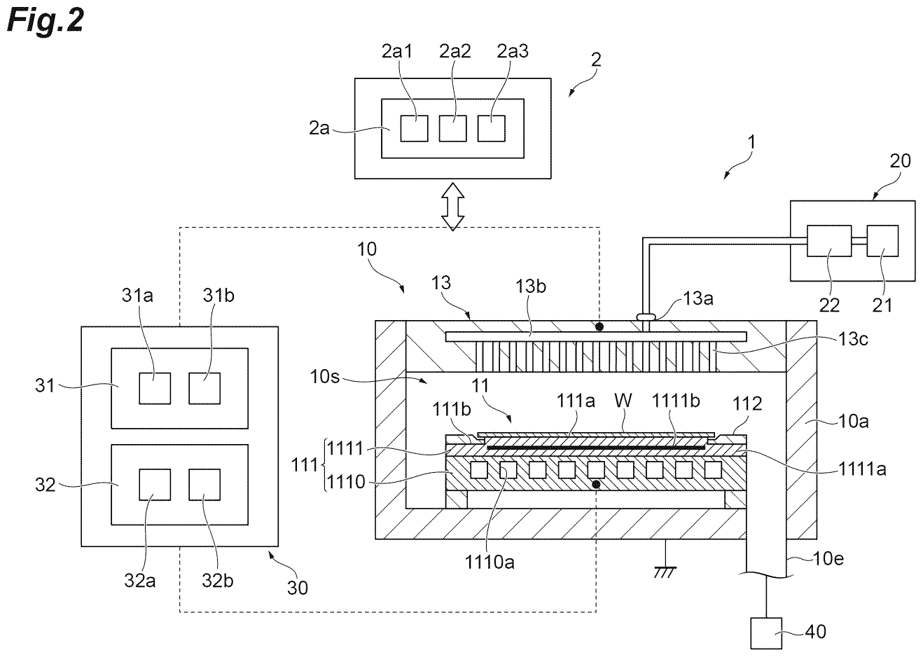

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode (also referred to as an adsorption electrode, a chuck electrode, or a clamp electrode) 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or a DC signal described below are supplied to the at least one RF/DC electrode, the RF/DC electrode is also called a bias electrode. It is noted that the conductive member of the base 1110 and the at least one RF/DC electrode may function as a plurality of lower electrodes. The electrostatic electrode 1111b may also function as a lower electrode. The substrate support 11 accordingly includes at least one lower electrode.

The ring assembly 112 includes one or more annular members. In an embodiment, the one or more annular members include one or more edge rings and at least one cover ring. The one or more edge rings are composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may include a heater, a heat transfer medium, a flow passage 1110a, or any combination thereof. A heat transfer fluid, such as brine or gas, flows into the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors (SGIs) provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may include, for example, a mass flow controller or a pressure-controlled flow controller. The gas supply 20 may include at least one flow modulation device that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular, trapezoidal, or triangular waveform, or a combined waveform thereof. In an embodiment, a waveform generator for generating a sequence of voltage pulses from the DC signal is connected between the first DC generator 32a and the at least one lower electrode. The first DC generator 32a and the waveform generator thereby function as a voltage pulse generator. In the case that the second DC generator 32b and the waveform generator function as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may include a turbo-molecular pump, a dry pump, or a combination thereof.

In the capacitively coupled plasma processing apparatus 1, the upper electrode is disposed such that the plasma processing space is located between the upper electrode and the substrate support 11. A radio frequency power supply such as the first RF generator 31a is electrically connected to the upper electrode or the lower electrode in the substrate support 11. When the plasma processing apparatus 1 is an inductively coupled plasma processing apparatus, an antenna is disposed such that the plasma processing space is located between the antenna and the substrate support 11. A radio frequency power supply such as the first RF generator 31a is electrically connected to the antenna. When the plasma processing apparatus 1 is a plasma processing apparatus that generates plasma by a surface wave such as a microwave, an antenna is disposed such that the plasma processing space is located between the antenna and the substrate support 11. A radio frequency power supply such as the first RF generator 31a is electrically connected to the antenna via a waveguide.

Hereinafter, plasma processing apparatuses according to various example embodiments will be described. Each plasma processing apparatus described below is configured to supply power to at least one power consuming member or at least one load in the chamber 10 by wireless power supply (electromagnetic induction coupling), and may have the same configuration as the plasma processing apparatus 1.

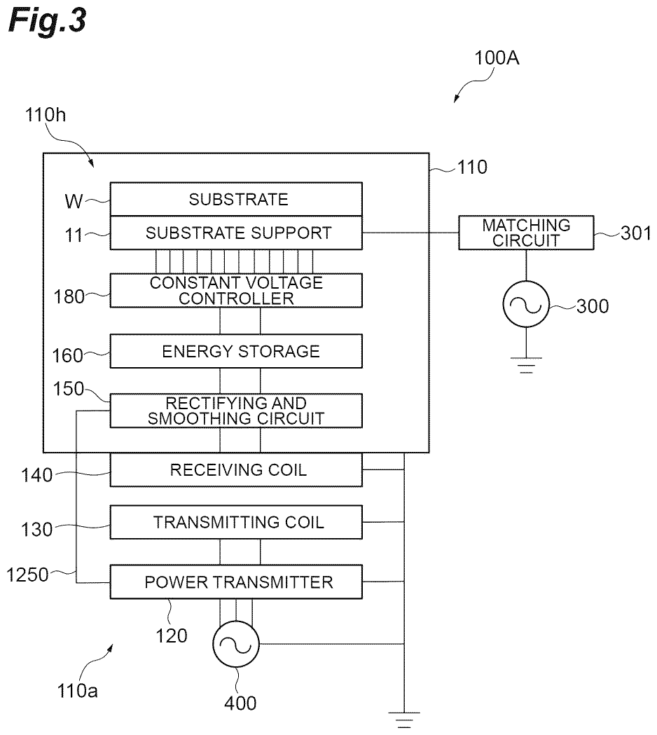

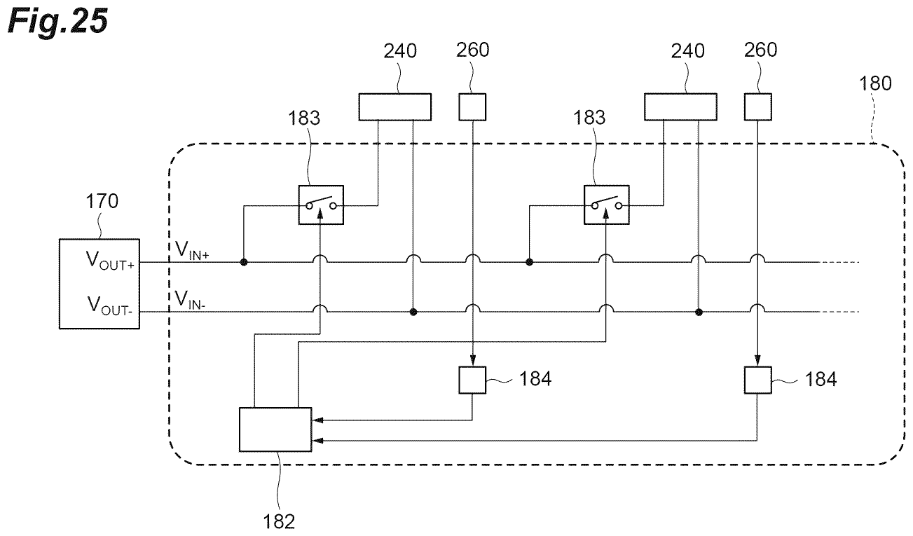

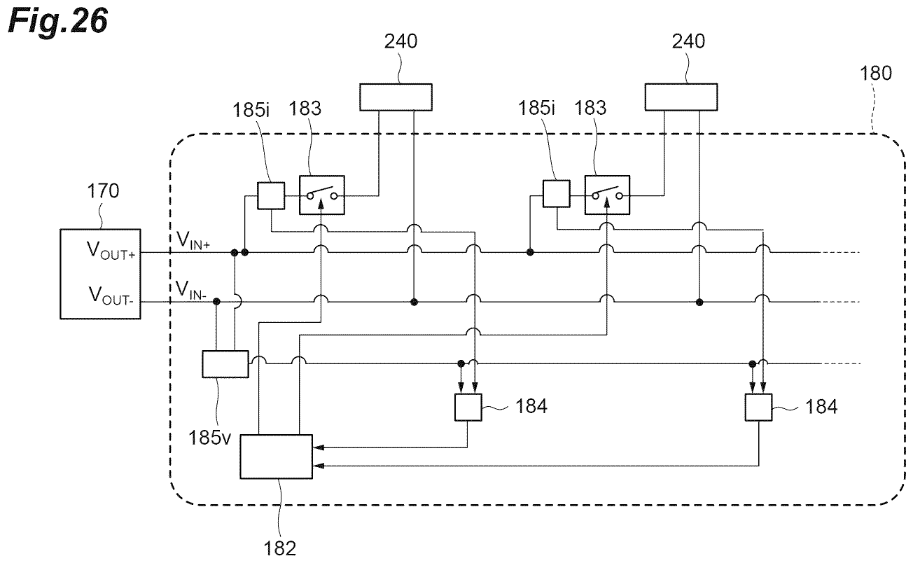

FIG. 3 is a diagram schematically illustrating a plasma processing apparatus according to one example embodiment. The plasma processing apparatus 100A illustrated in FIG. 3 includes at least one radio frequency power supply 300, a receiving coil module 140, an energy storage 160, and at least one power consuming member 240 which is at least one load (see FIGS. 25 and 26). The plasma processing apparatus 100A may further include a power transmitter 120, a transmitting coil module 130, a rectifying and smoothing circuit 150, a constant voltage controller 180 (an example of a voltage controller), a ground frame 110, and a matching circuit 301.

The at least one radio frequency power supply 300 includes the first RF generator 31a and/or the second RF generator 31b. The at least one radio frequency power supply 300 is electrically connected to the substrate support 11 via the matching circuit 301. The matching circuit 301 includes at least one impedance matching circuit.

The ground frame 110 includes the chamber 10 and is electrically grounded. The ground frame 110 electrically separates an interior space 110h (RF-Hot space) thereof from an exterior space 110a (atmospheric space). The ground frame 110 surrounds the substrate support 11 disposed in the space 110h. In the plasma processing apparatus 100A, the rectifying and smoothing circuit 150, the energy storage 160, and the constant voltage controller 180 are disposed in the space 110h. In the plasma processing apparatus 100A, the power transmitter 120, the transmitting coil module 130, and the receiving coil module 140 are disposed in the space 110a. The space 110h includes a reduced-pressure space (vacuum space) and a non-reduced-pressure space (non-vacuum space). The reduced-pressure space is a space inside the chamber 10, and the non-reduced-pressure space is a space outside the chamber 10. The substrate support 11 and the substrate W are disposed in the reduced-pressure space. The rectifying and smoothing circuit 150, the energy storage 160, and the constant voltage controller 180 are disposed in the non-reduced-pressure space.

The devices disposed in the space 110a, namely the power transmitter 120, the transmitting coil module 130, the receiving coil module 140, and the like, are covered by a metal housing formed of a metal such as aluminum, and the metal housing is grounded. This suppresses leakage of radio frequency noise caused by radio frequency power such as the first RF signal (source RF signal) and/or the second RF signal (bias RF signal). The metal housing and each power supply line have an insulation distance therebetween. In the following description, radio frequency power such as the first RF signal and/or the second RF signal that propagates toward the power transmitter 120 may be referred to as radio frequency noise, common mode noise, or conducted noise.

The power transmitter 120 is electrically connected between an AC power source 400 (for example, a commercial AC power source) and the transmitting coil module 130. The power transmitter 120 receives AC power from the AC power source 400 and converts the frequency of the AC power into a transmission frequency, thereby generating AC power having the transmission frequency, that is, transmission AC power.

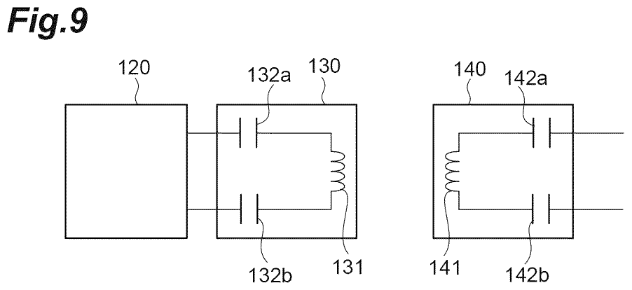

The transmitting coil module 130 includes a transmitting coil 131 (see FIG. 9) described below. The transmitting coil 131 is electrically connected to the power transmitter 120. The transmitting coil 131 receives the transmission AC power from the power transmitter 120 and wirelessly transmits the transmission AC power to the receiving coil 141.

The receiving coil module 140 includes a receiving coil 141 (see FIG. 9) described below. The receiving coil 141 is electromagnetically inductively coupled to the transmitting coil 131. Electromagnetic induction coupling includes magnetic field coupling and electric field coupling. Magnetic field coupling also includes magnetic resonance (also referred to as magnetic field resonance). The distance between the receiving coil 141 and the transmitting coil 131 is set so as to suppress common mode noise (conducted noise). The distance between the receiving coil 141 and the transmitting coil 131 is also set to a distance at which power can be supplied. The distance between the receiving coil 141 and the transmitting coil 131 is set such that the attenuation of radio frequency power (i.e., radio frequency noise) between the receiving coil 141 and the transmitting coil 131 is equal to or less than a threshold value, and such that power from the transmitting coil 131 can be received by the receiving coil 141. The threshold value of the attenuation is set to a value that can sufficiently prevent damage or malfunction of the power transmitter 120. The threshold value of the attenuation is, for example, −20 dB. The transmission AC power received by the receiving coil module 140 is output to the rectifying and smoothing circuit 150.

The rectifying and smoothing circuit 150 is electrically connected between the receiving coil module 140 and the energy storage 160. The rectifying and smoothing circuit 150 generates DC power by full-wave rectification and smoothing of the transmission AC power from the receiving coil module 140. The DC power generated by the rectifying and smoothing circuit 150 is stored in the energy storage 160. The energy storage 160 is electrically connected between the rectifying and smoothing circuit 150 and the constant voltage controller 180. The rectifying and smoothing circuit 150 may generate DC power by half-wave rectification and smoothing of the transmission AC power from the receiving coil module 140.

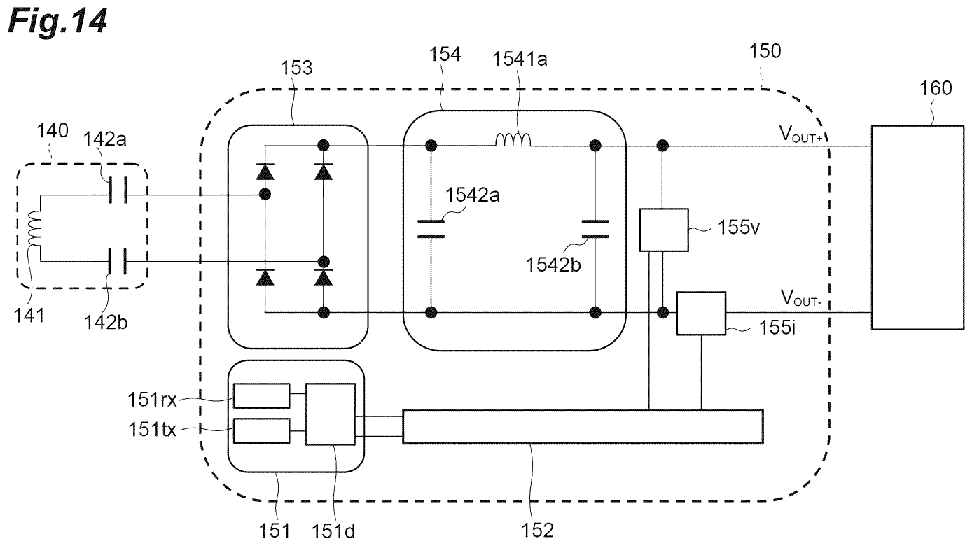

The rectifying and smoothing circuit 150 and the power transmitter 120 are electrically connected to each other by a signal line 1250. The rectifying and smoothing circuit 150 transmits an instruction signal to the power transmitter 120 via the signal line 1250. The instruction signal is a signal for instructing the power transmitter 120 to supply the transmission AC power or to stop the supply of the transmission AC power. The instruction signal may include a status signal, an abnormality detection signal, and a cooling control signal for the transmitting coil module 130 and the receiving coil module 140. The status signal is a value such as the magnitude and/or phase of voltage, current, and power detected by a voltage detector 155v (see FIG. 14) and a current detector 155i (see FIG. 14) of the rectifying and smoothing circuit 150. The abnormality detection signal is a signal for notifying the power transmitter 120 of the occurrence of a failure and/or a temperature abnormality of the rectifying and smoothing circuit 150. The cooling control signal controls cooling mechanisms provided in the transmitting coil module 130 and the receiving coil module 140. The cooling control signal controls, for example, the rotation speed of a fan in the case of air cooling. In the case of liquid cooling, the cooling control signal controls the flow velocity and/or temperature, or the like of the refrigerant.

The constant voltage controller 180 applies a voltage to at least the power consuming member 240 using the power stored in the energy storage 160. The constant voltage controller 180 can control the application of a voltage to at least the power consuming member 240 and the stopping thereof.

In the plasma processing apparatus 100A, the receiving coil 141 functions as a filter against radio frequency noise caused by radio frequency power such as the first RF signal and/or the second RF signal. Therefore, propagation of radio frequency noise to a power source external to the plasma processing apparatus is suppressed.

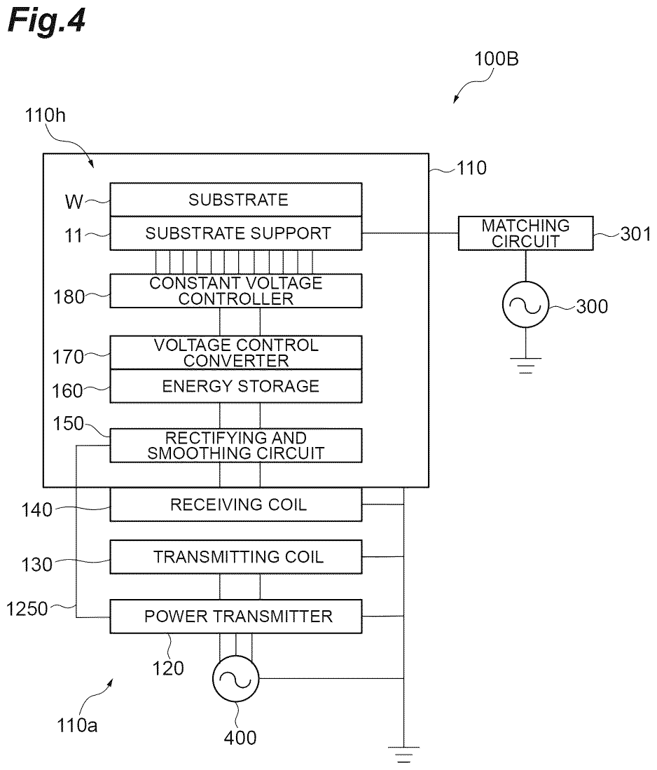

Reference is made to FIG. 4. FIG. 4 is a diagram schematically illustrating a plasma processing apparatus according to another example embodiment. Hereinafter, the plasma processing apparatus 100B illustrated in FIG. 4 will be described from the perspective of its differences from the plasma processing apparatus 100A.

The plasma processing apparatus 100B further includes a voltage control converter 170. The voltage control converter 170 is a DC-DC converter and is connected between the energy storage 160 and the constant voltage controller 180. The voltage control converter 170 may be configured to input a constant output voltage to the constant voltage controller 180 even when a voltage fluctuation occurs in the energy storage 160. The voltage fluctuation in the energy storage 160 may occur, for example, as a voltage drop or the like corresponding to the stored power when the energy storage 160 is configured with an electric double layer capacitor.

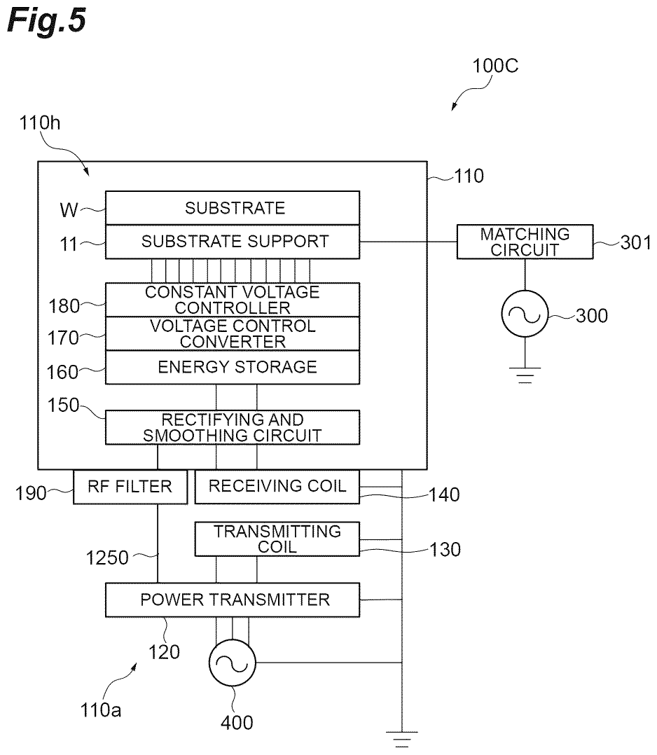

Reference is made to FIG. 5. FIG. 5 is a diagram schematically illustrating a plasma processing apparatus according to yet another example embodiment. Hereinafter, the plasma processing apparatus 100C illustrated in FIG. 5 will be described from the perspective of its differences from the plasma processing apparatus 100B.

The plasma processing apparatus 100C further includes an RF filter 190. The RF filter 190 is connected between the rectifying and smoothing circuit 150 and the power transmitter 120. The RF filter 190 provides a part of the signal line 1250. The RF filter 190 has a characteristic of suppressing propagation of radio frequency power (radio frequency noise) via the signal line 1250. That is, the RF filter 190 includes a low-pass filter having a characteristic of having high impedance against radio frequency noise (conducted noise) but passing an instruction signal of a relatively low frequency.

In the plasma processing apparatus 100C, the energy storage 160, the voltage control converter 170, and the constant voltage controller 180 are integrated with each other. That is, the energy storage 160, the voltage control converter 170, and the constant voltage controller 180 are all disposed in a single metal housing or formed on a single circuit board. This shortens the length of each of a pair of power supply lines (a plus line and a minus line) connecting the energy storage 160 and the voltage control converter 170 to each other. It is also possible to make the lengths of the pair of power supply lines connecting the energy storage 160 and the voltage control converter 170 to each other equal to each other. Also, the length of each of a pair of power supply lines (a plus line and a minus line) connecting the voltage control converter 170 and the constant voltage controller 180 to each other is shortened. It is also possible to make the lengths of the pair of power supply lines connecting the voltage control converter 170 and the constant voltage controller 180 to each other equal to each other. Therefore, malfunction and damage of devices caused by normal mode noise (potential difference between the plus line and the minus line) are suppressed. When another metal body that shields an electromagnetic field around the housing is provided in the chamber 10, the single housing need not be made of metal.

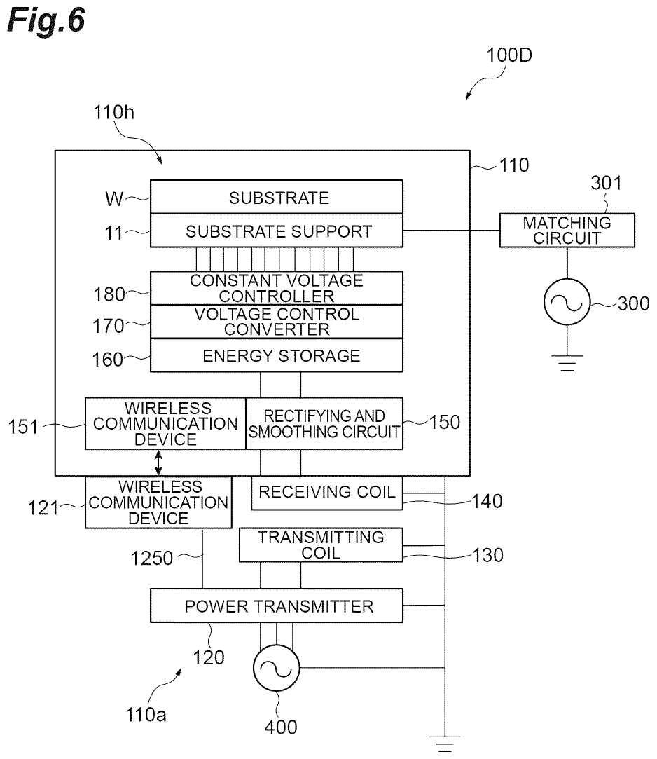

Reference is made to FIG. 6. FIG. 6 is a diagram schematically illustrating a plasma processing apparatus according to yet another example embodiment. Hereinafter, the plasma processing apparatus 100D illustrated in FIG. 6 will be described from the perspective of its differences from the plasma processing apparatus 100C.

The plasma processing apparatus 100D does not include the RF filter 190. In the plasma processing apparatus 100D, the rectifying and smoothing circuit 150 includes a communication device 151 that is a wireless communication device. The communication device 151 is disposed in the non-reduced-pressure space. The power transmitter 120 also includes a communication device 121 that is a wireless communication device. The communication device 121 is disposed in the space 110a. The above-described instruction signal is transmitted between the rectifying and smoothing circuit 150 and the power transmitter 120 using the communication device 151 and the communication device 121. Details of the communication device 121 and the communication device 151 will be described below.

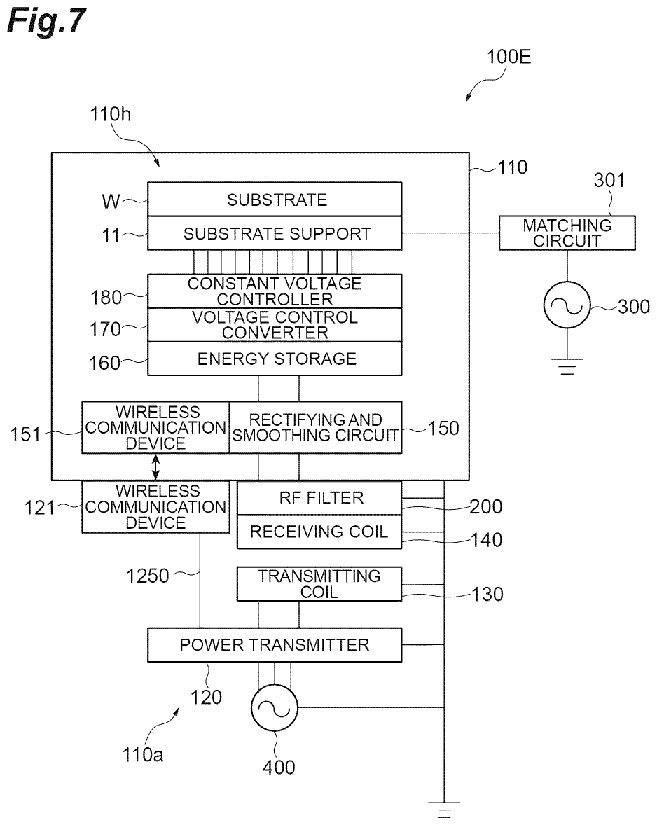

Reference is made to FIG. 7. FIG. 7 is a diagram schematically illustrating a plasma processing apparatus according to yet another example embodiment. Hereinafter, the plasma processing apparatus 100E illustrated in FIG. 7 will be described from the perspective of its differences from the plasma processing apparatus 100D.

The plasma processing apparatus 100E further includes an RF filter 200. The RF filter 200 is connected between the receiving coil module 140 and the rectifying and smoothing circuit 150. The RF filter 200 has a characteristic of reducing or blocking radio frequency noise propagating from the receiving coil module 140 to the transmitting coil 131 and the power transmitter 120. Details of the RF filter 200 will be described below.

Hereinafter, the configuration of each component for wireless power supply in the plasma processing apparatuses according to various example embodiments will be described in detail.

### Configuration of Power transmitter

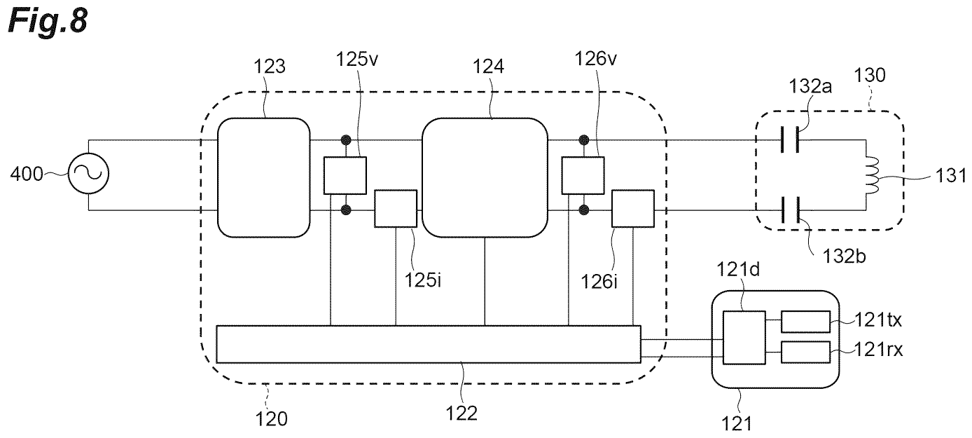

FIG. 8 is a diagram illustrating a power transmitter according to one example embodiment. As described above, the power transmitter 120 receives AC power from the AC power source 400 and converts the frequency of the AC power into a transmission frequency, thereby generating transmission AC power having the transmission frequency.

In one embodiment, the power transmitter 120 includes a controller 122, a rectifying and smoothing circuit 123, and an inverter 124. The controller 122 includes a processor such as a CPU or a programmable logic device such as an FPGA (Field-Programmable Gate Array).

The rectifying and smoothing circuit 123 includes a rectifier circuit and a smoothing circuit. The rectifier circuit includes, for example, a diode bridge. The smoothing circuit includes, for example, a line capacitor. The rectifying and smoothing circuit 123 generates DC power by full-wave rectification and smoothing of the AC power from the AC power source 400. The rectifying and smoothing circuit 123 may generate DC power by half-wave rectification and smoothing of the AC power from the AC power source 400.

The inverter 124 generates transmission AC power having a transmission frequency from the DC power output by the rectifying and smoothing circuit 123. The inverter 124 is, for example, a full-bridge inverter and includes a plurality of triacs or a plurality of switching elements (for example, FETs). The inverter 124 generates the transmission AC power by ON/OFF control of the plurality of triacs or the plurality of switching elements by the controller 122. The transmission AC power output from the inverter 124 is output to the transmitting coil module 130.

The power transmitter 120 may further include a voltage detector 125v, a current detector 125i, a voltage detector 126v, and a current detector 126i. The voltage detector 125v detects a voltage value between a pair of power supply lines connecting the rectifying and smoothing circuit 123 and the inverter 124 to each other. The current detector 125i detects a current value between the rectifying and smoothing circuit 123 and the inverter 124. The voltage detector 126v detects a voltage value between a pair of power supply lines connecting the inverter 124 and the transmitting coil module 130 to each other. The current detector 126i detects a current value between the inverter 124 and the transmitting coil module 130. The voltage value detected by the voltage detector 125v, the current value detected by the current detector 125i, the voltage value detected by the voltage detector 126v, and the current value detected by the current detector 126i are notified to the controller 122.

The power transmitter 120 includes the above-described communication device 121. The communication device 121 includes a driver 121d, a transmitter 121tx, and a receiver 121rx. The transmitter 121tx is a transmitter of a wireless signal or a transmitter of an optical signal. The receiver 121rx is a receiver of a wireless signal or a receiver of an optical signal. The communication device 121 drives the transmitter 121tx by the driver 121d to cause the transmitter 121tx to output a signal from the controller 122 as a wireless signal or an optical signal. The signal output from the transmitter 121tx is received by the communication device 151 (see FIG. 14) described below. The communication device 121 also receives a signal such as the above-described instruction signal from the communication device 151 by the receiver 121rx and inputs the received signal to the controller 122 via the driver 121d. The controller 122 controls the inverter 124 in accordance with the instruction signal received from the communication device 151 via the communication device 121, the voltage value detected by the voltage detector 125v, the current value detected by the current detector 125i, the voltage value detected by the voltage detector 126v, and the current value detected by the current detector 126i, thereby switching between output of the transmission AC power and stopping thereof.

### Transmitting Coil Module and Receiving Coil Module

Reference is made to FIGS. 9 to 11. Each of FIGS. 9 to 11 is a diagram illustrating a transmitting coil module and a receiving coil module according to one example embodiment. As illustrated in FIG. 9, the transmitting coil module 130 may include, in addition to the transmitting coil 131, a resonance capacitor 132a and a resonance capacitor 132b. The resonance capacitor 132a is connected between one of a pair of power supply lines connecting the power transmitter 120 and the transmitting coil module 130 to each other and one end of the transmitting coil 131. The resonance capacitor 132b is connected between the other of the pair of power supply lines and the other end of the transmitting coil 131. The transmitting coil 131, the resonance capacitor 132a, and the resonance capacitor 132b form a resonance circuit for the transmission frequency. That is, the transmitting coil 131, the resonance capacitor 132a, and the resonance capacitor 132b have a resonance frequency that substantially matches the transmission frequency. The transmitting coil module 130 may omit either one of the resonance capacitor 132a and the resonance capacitor 132b.

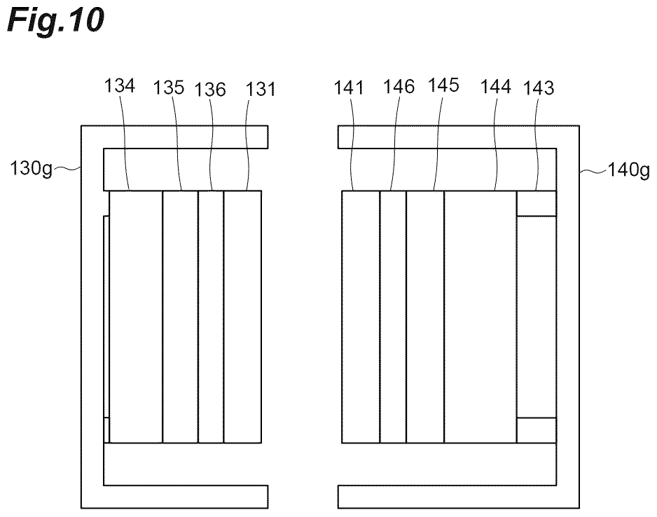

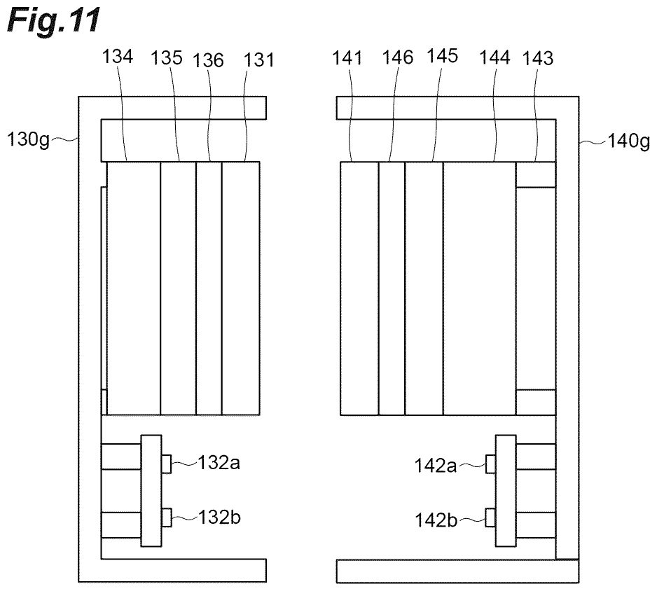

As illustrated in FIGS. 10 and 11, the transmitting coil module 130 may further include a metal housing 130g. The metal housing 130g has an open end and is grounded. The transmitting coil 131 is disposed in the metal housing 130g with an insulation distance secured. The transmitting coil module 130 may further include a heat sink 134, a back ferrite member 135, and a thermal conductive sheet 136. The heat sink 134 is disposed in the metal housing 130g and is supported by the metal housing 130g. The back ferrite member 135 is disposed on the heat sink 134. The thermal conductive sheet 136 is disposed on the back ferrite member 135. The transmitting coil 131 is disposed on the thermal conductive sheet 136 and faces the receiving coil 141 through the open end of the metal housing 130g. As illustrated in FIG. 11, the resonance capacitor 132a and the resonance capacitor 132b may further be accommodated in the metal housing 130g.

As illustrated in FIG. 9, the receiving coil module 140 includes a receiving coil 141. The receiving coil 141 is coupled to the transmitting coil 131 by electromagnetic induction. The receiving coil module 140 may include, in addition to the receiving coil 141, a resonance capacitor 142a and a resonance capacitor 142b. The resonance capacitor 142a is connected between one of a pair of power supply lines extending from the receiving coil module 140 and one end of the receiving coil 141. The resonance capacitor 142b is connected between the other of the pair of power supply lines and the other end of the receiving coil 141. The receiving coil 141, the resonance capacitor 142a, and the resonance capacitor 142b form a resonance circuit for the transmission frequency. That is, the receiving coil 141, the resonance capacitor 142a, and the resonance capacitor 142b have a resonance frequency that substantially matches the transmission frequency. The receiving coil module 140 may omit either one of the resonance capacitor 142a and the resonance capacitor 142b.

As illustrated in FIGS. 10 and 11, the receiving coil module 140 may further include a metal housing 140g. The metal housing 140g has an open end and is grounded. The receiving coil 141 is disposed in the metal housing 140g with an insulation distance secured. The receiving coil module 140 may further include a spacer 143, a heat sink 144, a back ferrite member 145, and a thermal conductive sheet 146. The spacer 143 is disposed in the metal housing 140g and is supported by the metal housing 140g. The spacer 143 will be described below. The heat sink 144 is disposed on the spacer 143. The back ferrite member 145 is disposed on the heat sink 144. The thermal conductive sheet 146 is disposed on the back ferrite member 145. The receiving coil 141 is disposed on the thermal conductive sheet 146 and faces the transmitting coil 131 through the open end of the metal housing 140g. As illustrated in FIG. 11, the resonance capacitor 142a and the resonance capacitor 142b may further be accommodated in the metal housing 140g.

The spacer 143 is formed of a dielectric material and is provided between the receiving coil 141 and the metal housing 140g (ground). The spacer 143 provides a stray capacitance in a space between the receiving coil 141 and the ground.

### Impedance Characteristics of Receiving Coil Module

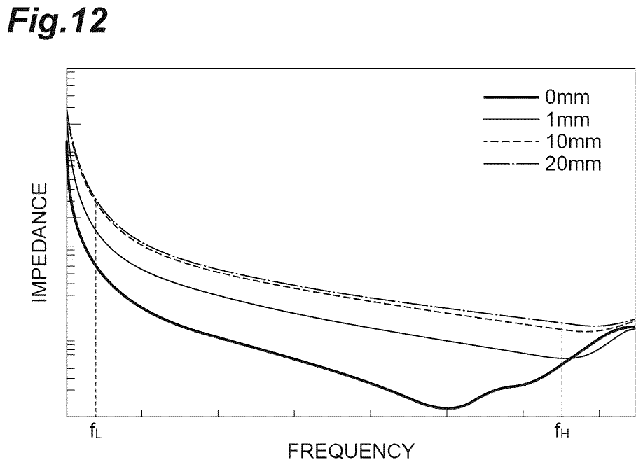

Reference is made to FIG. 12. FIG. 12 is a graph illustrating impedance characteristics of a receiving coil module according to one example embodiment. FIG. 12 illustrates the impedance characteristics of the receiving coil module 140 according to the thickness of the spacer 143. The thickness of the spacer 143 corresponds to the distance between the heat sink 144 and the metal housing 140g. As illustrated in FIG. 12, the receiving coil module 140 can adjust the impedance at each of the frequency f_{H} and the frequency f_{L} according to the thickness of the spacer 143. Therefore, with the receiving coil module 140, high impedance can be provided at each of the frequencies of two radio frequency powers used in the plasma processing apparatus, such as the first RF signal and the second RF signal. In addition, since high impedance can be obtained in the receiving coil module 140, loss of radio frequency power can be suppressed, and a high processing rate (for example, etching rate) can be obtained.

### RF Filter 200

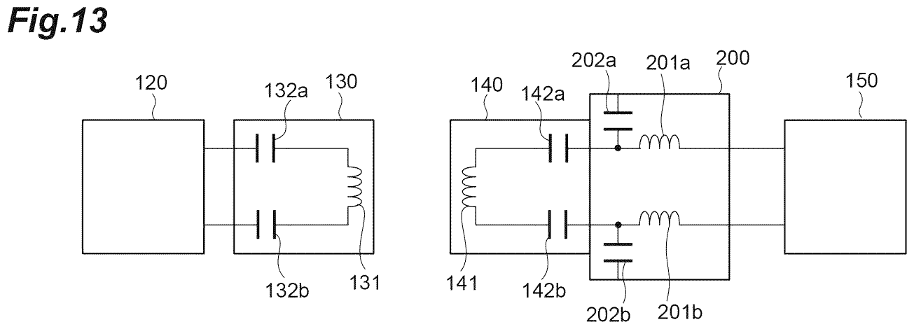

Reference is made to FIG. 13. FIG. 13 is a diagram illustrating an RF filter according to one example embodiment. As illustrated in FIG. 13, the RF filter 200 is connected between the receiving coil module 140 and the rectifying and smoothing circuit 150. The RF filter 200 includes an inductor 201a, an inductor 201b, a termination capacitor 202a, and a termination capacitor 202b. One end of the inductor 201a is connected to the resonance capacitor 142a, and the other end of the inductor 201a is connected to the rectifying and smoothing circuit 150. One end of the inductor 201b is connected to the resonance capacitor 142b, and the other end of the inductor 201b is connected to the rectifying and smoothing circuit 150. The termination capacitor 202a is connected between one end of the inductor 201a and ground. The termination capacitor 202b is connected between one end of the inductor 201b and ground. The inductor 201a and the termination capacitor 202a form a low-pass filter. The inductor 201b and the termination capacitor 202b also form a low-pass filter. With the RF filter 200, high impedance is obtained at each of the frequencies of two radio frequency powers used in the plasma processing apparatus, such as the first RF signal and the second RF signal. Therefore, loss of radio frequency power is suppressed, and a high processing rate (for example, etching rate) can be obtained.

### Rectifying and Smoothing Circuit

Reference is made to FIG. 14. FIG. 14 is a diagram illustrating a rectifying and smoothing circuit according to one example embodiment. In one embodiment, the rectifying and smoothing circuit 150 includes a controller 152, a rectifier circuit 153, and a smoothing circuit 154. The rectifier circuit 153 is connected between the receiving coil module 140 and the smoothing circuit 154. The smoothing circuit 154 is connected between the rectifier circuit 153 and the energy storage 160. The controller 152 includes a processor such as a CPU or a programmable logic device such as an FPGA (Field-Programmable Gate Array). The controller 152 may be the same as or different from the controller 122.

The rectifier circuit 153 outputs power generated by full-wave rectification of the AC power from the receiving coil module 140. The rectifier circuit 153 is, for example, a diode bridge. The rectifier circuit 153 may output power generated by half-wave rectification of the AC power from the receiving coil module 140.

The smoothing circuit 154 generates DC power by smoothing the power from the rectifier circuit 153. The smoothing circuit 154 may include an inductor 1541a, a capacitor 1542a, and a capacitor 1542b. One end of the inductor 1541a is connected to one of a pair of inputs of the smoothing circuit 154. The other end of the inductor 1541a is connected to a positive output (V_{OUT+}) of the rectifying and smoothing circuit 150. The positive output of the rectifying and smoothing circuit 150 is connected to one end of each of one or more capacitors of the energy storage 160 via a plus line 160p of a pair of power supply lines described below (see FIG. 23A and FIG. 23B).

One end of the capacitor 1542a is connected to one of the pair of inputs of the smoothing circuit 154 and one end of the inductor 1541a. The other end of the capacitor 1542a is connected to the other of a pair of outputs of the smoothing circuit 154 and a negative output (V_{OUT-}) of the rectifying and smoothing circuit 150. The negative output of the rectifying and smoothing circuit 150 is connected to the other end of each of the one or more capacitors of the energy storage 160 via a minus line 160m of the pair of power supply lines described below (see FIG. 23A and FIG. 23B). One end of the capacitor 1542b is connected to the other end of the inductor 1541a. The other end of the capacitor 1542b is connected to the other of the pair of outputs of the smoothing circuit 154 and the negative output (V_{OUT-}) of the rectifying and smoothing circuit 150.

The rectifying and smoothing circuit 150 may further include a voltage detector 155v and a current detector 155i. The voltage detector 155v detects a voltage value between the positive output and the negative output of the rectifying and smoothing circuit 150. The current detector 155i detects a current value between the rectifying and smoothing circuit 150 and the energy storage 160. The voltage value detected by the voltage detector 155v and the current value detected by the current detector 155i are notified to the controller 152. The controller 152 generates the above-described instruction signal in accordance with the power stored in the energy storage 160. For example, when the power stored in the energy storage 160 is equal to or less than a first threshold value, the controller 152 generates an instruction signal for instructing the power transmitter 120 to supply power, that is, to output the transmission AC power. The first threshold value is, for example, the power consumed by a load such as the power consuming member 240. The first threshold value may also be a value obtained by multiplying the power consumed by a load such as the power consuming member 240 by a constant value (for example, a value in a range of 1 or more and 3 or less) in consideration of a margin. On the other hand, when the power stored in the energy storage 160 is greater than a second threshold value, the controller 152 generates an instruction signal for instructing the power transmitter 120 to stop power supply, that is, to stop output of the transmission AC power. The second threshold value is a value that does not exceed the limit stored power of the energy storage 160. The second threshold value is, for example, a value obtained by multiplying the limit stored power of the energy storage 160 by a constant value (for example, a value of 1 or less).

The rectifying and smoothing circuit 150 includes the above-described communication device 151. The communication device 151 includes a driver 151d, a transmitter 151tx, and a receiver 151rx. The transmitter 151tx is a transmitter of a wireless signal or a transmitter of an optical signal. The receiver 151rx is a receiver of a wireless signal or a receiver of an optical signal. The communication device 151 drives the transmitter 151tx by the driver 151d to cause the transmitter 151tx to output a signal from the controller 152 such as an instruction signal as a wireless signal or an optical signal. The signal output from the transmitter 151tx is received by the communication device 121 of the power transmitter 120. The communication device 151 also receives a signal from the communication device 121 by the receiver 151rx and inputs the received signal to the controller 152 via the driver 151d.

### RF Filter 190

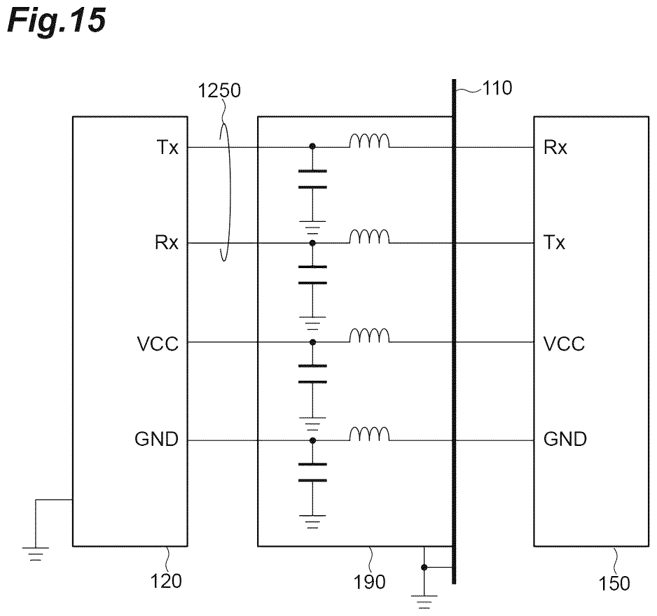

Reference is made to FIG. 15. FIG. 15 is a diagram illustrating an RF filter 190 according to one example embodiment. As illustrated in FIG. 15, the signal line 1250 may include a first signal line electrically connecting a signal output (Tx) of the power transmitter 120 and a signal input (Rx) of the rectifying and smoothing circuit 150, and a second signal line electrically connecting a signal input (Rx) of the power transmitter 120 and a signal output (Tx) of the rectifying and smoothing circuit 150. The signal line 1250 may include a signal line connecting a first reference voltage terminal (VCC) of the power transmitter 120 and a first reference voltage terminal (VCC) of the rectifying and smoothing circuit 150, and a signal line connecting a second reference voltage terminal (GND) of the power transmitter 120 and a second reference voltage terminal (GND) of the rectifying and smoothing circuit 150. The signal line 1250 may be a shielded cable covered with a shield at ground potential. In this case, the plurality of signal lines forming the signal line 1250 may be individually covered with a shield one by one, or may be collectively covered with a shield. The RF filter 190 provides a low-pass filter to each of the plurality of signal lines forming the signal line 1250. The low-pass filter may be an LC filter including an inductor and a capacitor. The inductor of the low-pass filter forms a part of the corresponding signal line. The capacitor is connected between one end of the inductor connected to the power transmitter 120 and ground. With the RF filter 190, propagation of radio frequency power (radio frequency noise) via the signal line 1250 between the rectifying and smoothing circuit 150 and the power transmitter 120 can be suppressed.

### Communication Device of Power Transmitter and Communication Device of Rectifying and Smoothing Circuit

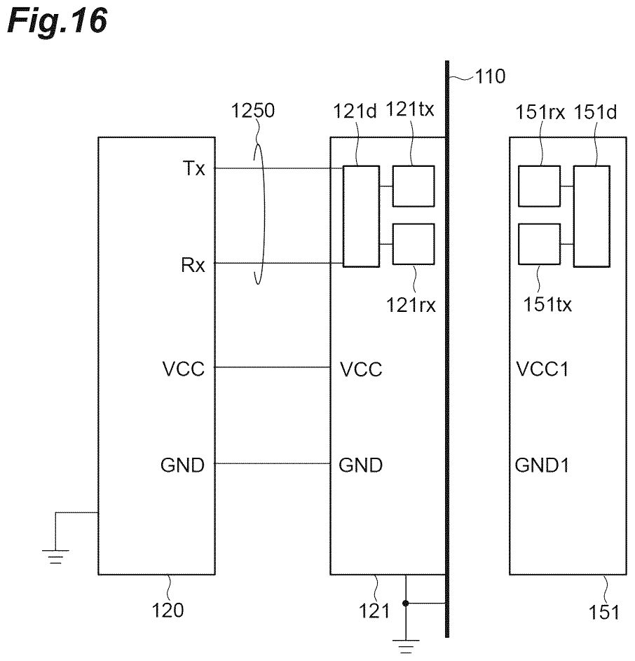

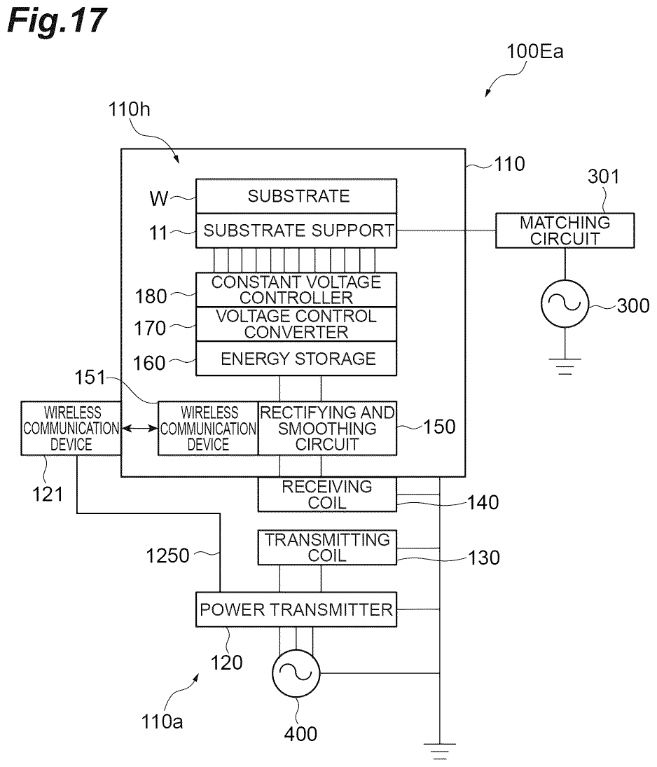

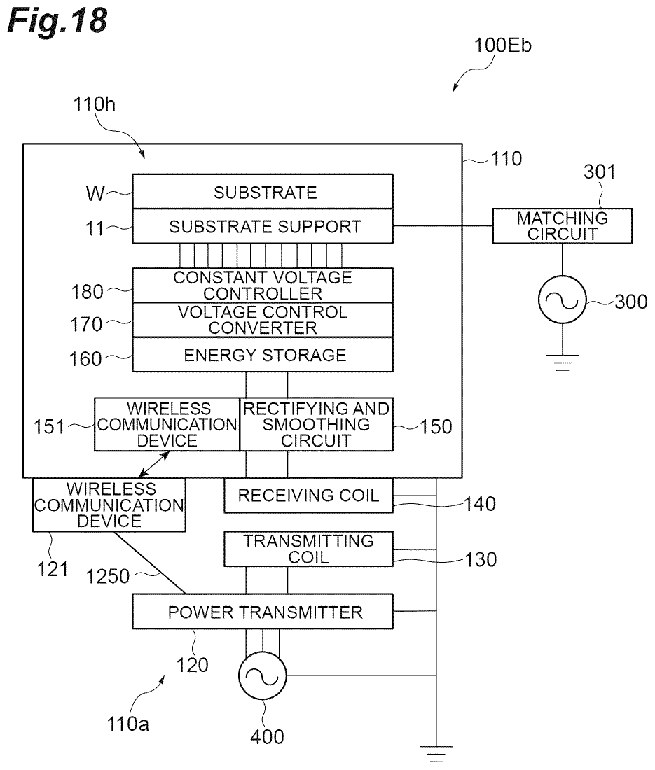

Reference is made to FIGS. 16 to 18. FIG. 16 is a diagram illustrating a communication device of a power transmitter and a communication device of a rectifying and smoothing circuit according to one example embodiment. Each of FIGS. 17 and 18 is a diagram schematically illustrating a plasma processing apparatus according to yet another example embodiment. As illustrated in FIGS. 6, 7, 16, 17, and 18, the communication device 121 and the communication device 151 may be configured to transmit a signal such as the above-described instruction signal between each other via wireless communication. Communication via wireless communication may be performed by optical communication. When the communication device 121 and the communication device 151 transmit signals between each other via wireless communication, the communication device 121 and the communication device 151 may be disposed at any position as long as no shielding object is interposed therebetween. In the examples illustrated in these figures, the RF filter 190 becomes unnecessary. In various example embodiments including the examples illustrated in FIGS. 16 to 18, the signal line 1250 may be a shielded cable covered with a shield at ground potential. In this case, the plurality of signal lines forming the signal line 1250 may be individually covered with a shield one by one, or may be collectively covered with a shield.

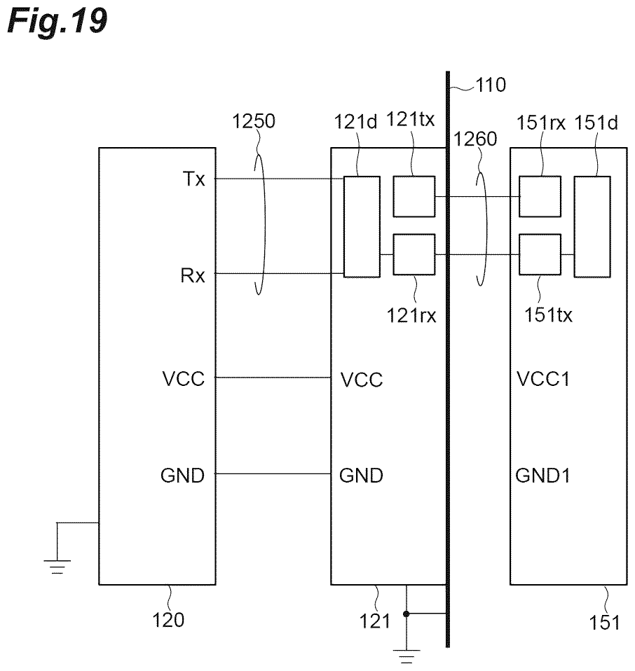

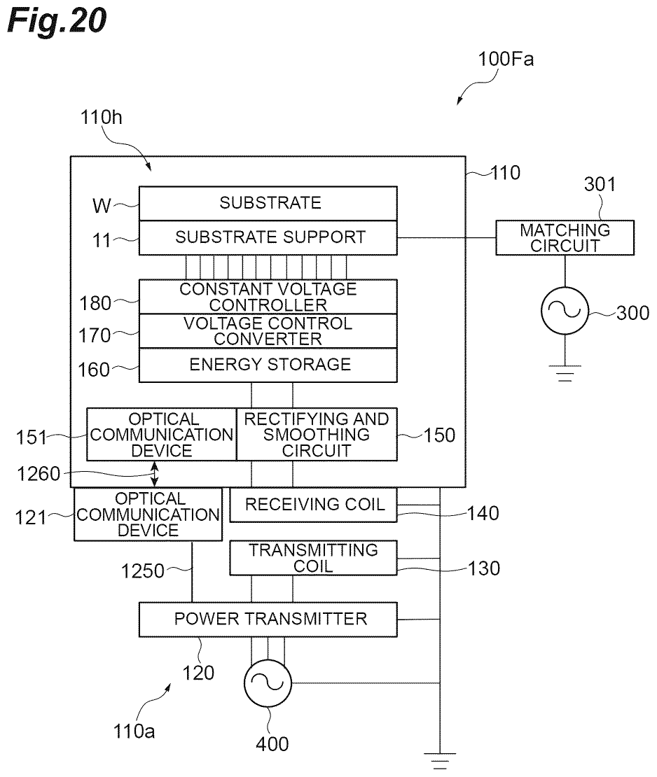

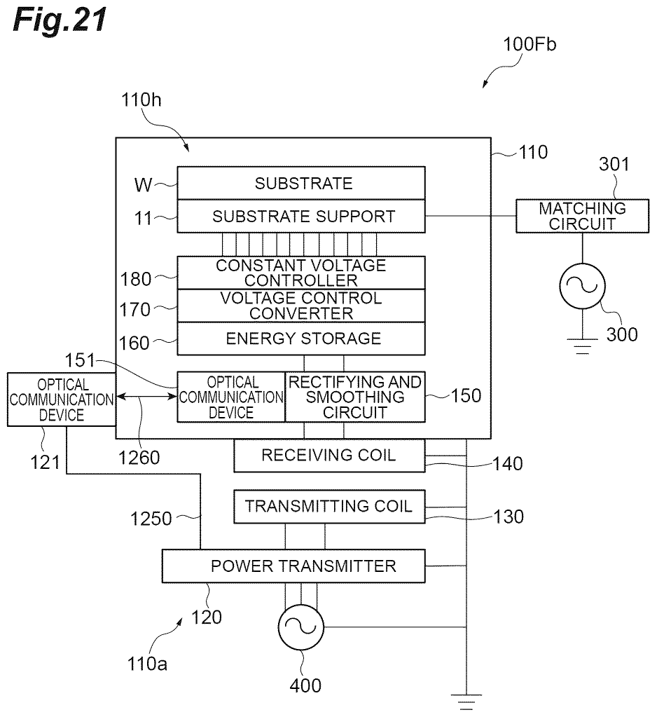

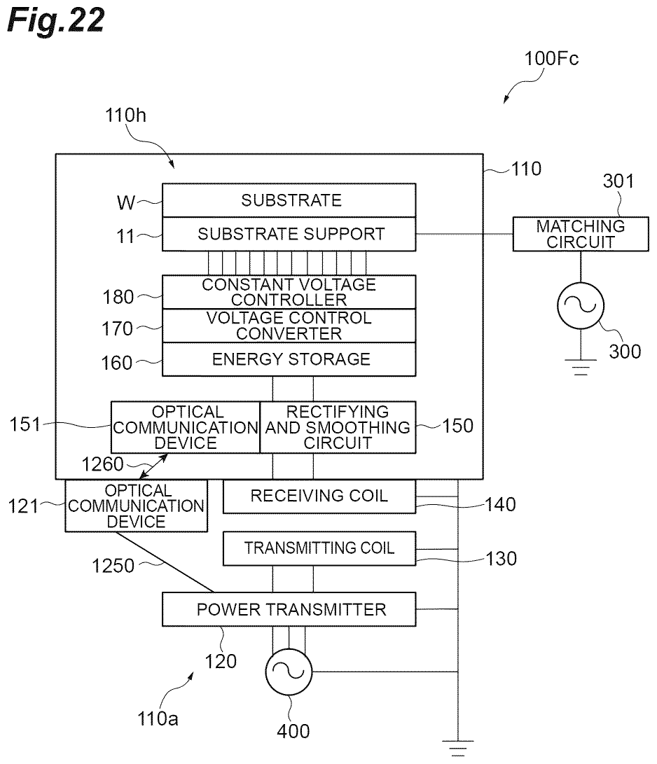

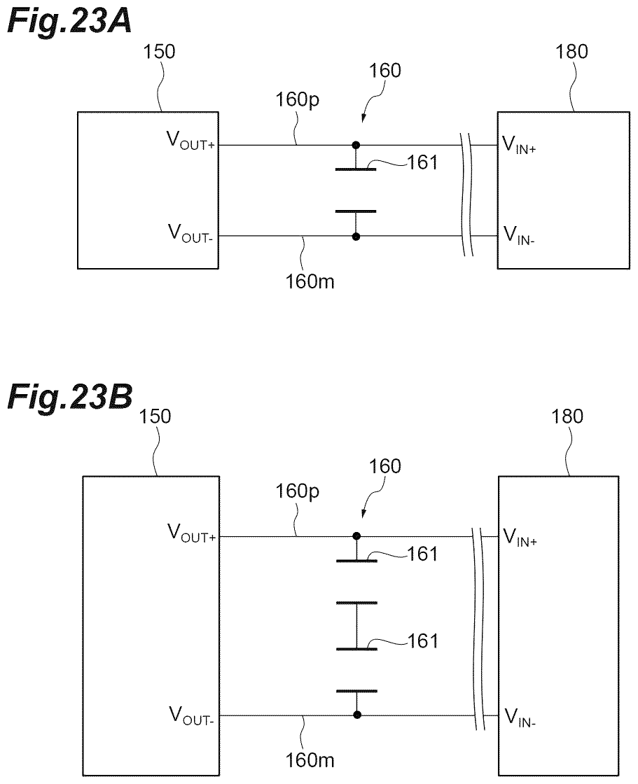

Reference is made to FIGS. 19 to 22. FIG. 19 is a diagram illustrating a communication device of a power transmitter and a communication device of a rectifying and smoothing circuit according to another example embodiment. Each of FIGS. 20 to 22 is a diagram schematically illustrating a plasma processing apparatus according to yet another example embodiment. As illustrated in FIGS. 19 to 22, the communication device 121 and the communication device 151 may be configured to transmit a signal (optical signal) such as the above-described instruction signal between each other via an optical fiber 1260, that is, by optical fiber communication. When the communication device 121 and the communication device 151 transmit signals between each other via the optical fiber 1260, the communication device 121 and the communication device 151 may be disposed at any position as long as the bending radius of the optical fiber 1260 is within an allowable range. In the examples illustrated in these figures as well, the RF filter 190 becomes unnecessary.

### Energy Storage

Reference is made to FIG. 23A and FIG. 23B. Each of FIG. 23A and FIG. 23B is a diagram illustrating an energy storage according to one example embodiment. As illustrated in FIG. 23A, the energy storage 160 includes a capacitor 161. The capacitor 161 is connected between a pair of power supply lines, namely a plus line 160p and a minus line 160m. The plus line 160p extends from the positive output (V_{OUT+}) of the rectifying and smoothing circuit 150 toward a load. The minus line 160m extends from the negative output (V_{OUT-}) of the rectifying and smoothing circuit 150 toward the load. The capacitor 161 may be a polarized capacitor. The capacitor 161 may be an electric double layer capacitor or a lithium-ion battery.

As illustrated in FIG. 23B, the energy storage 160 may include a plurality of capacitors 161. The plurality of capacitors 161 are connected in series between the plus line 160p and the minus line 160m. The plurality of capacitors 161 may have the same capacitance as each other or may have different capacitances from each other. Each of the plurality of capacitors 161 may be a polarized capacitor. Each of the plurality of capacitors 161 may be an electric double layer capacitor or a lithium-ion battery. The energy storage 160 needs to be used under a condition in which the sum of the input voltage applied thereto and the line-to-line potential difference due to normal mode noise is lower than the allowable input voltage. When the energy storage 160 includes a series connection of the plurality of capacitors 161, the allowable input voltage of the energy storage 160 becomes higher. Therefore, according to the example illustrated in FIG. 23B, the noise resistance of the energy storage 160 is improved.

### Voltage Control Converter

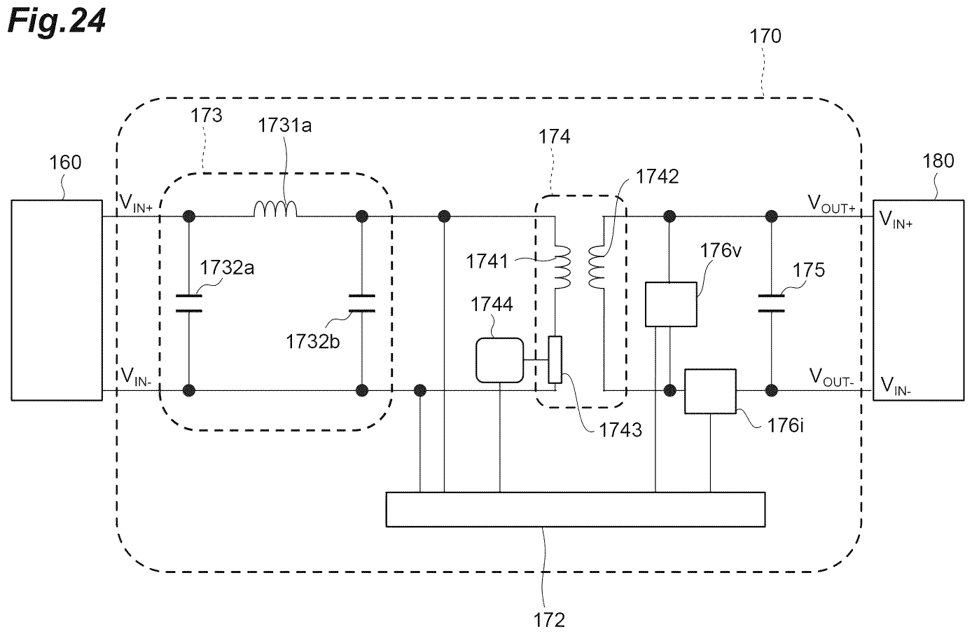

Reference is made to FIG. 24. FIG. 24 is a diagram illustrating a voltage control converter according to one example embodiment. The voltage control converter 170 is a DC-DC converter. The voltage control converter 170 is connected between the energy storage 160 and the constant voltage controller 180. The plus line 160p is connected to a positive input (V_{IN+}) of the voltage control converter 170. The minus line 160m is connected to a negative input (V_{IN-}) of the voltage control converter 170. A positive output (V_{OUT+}) of the voltage control converter 170 is connected to a positive input (V_{IN+}) of the constant voltage controller 180. A negative output (V_{OUT-}) of the voltage control converter 170 is connected to a negative input (V_{IN-}) of the constant voltage controller 180.

The voltage control converter 170 may include a controller 172, a low-pass filter 173, a transformer 174, and a capacitor 175. The low-pass filter 173 may include an inductor 1731a, a capacitor 1732a, and a capacitor 1732b. One end of the inductor 1731a is connected to the positive input (V_{IN+}) of the voltage control converter 170. The other end of the inductor 1731a is connected to one end of a primary coil of the transformer 174. One end of the capacitor 1732a is connected to one end of the inductor 1731a and the positive input (V_{IN+}) of the voltage control converter 170. The other end of the capacitor 1732a is connected to the negative input (V_{IN-}) of the voltage control converter 170. One end of the capacitor 1732b is connected to the other end of the inductor 1731a. The other end of the capacitor 1732b is connected to the negative input (V_{IN-}) of the voltage control converter 170.

The transformer 174 includes the primary coil 1741, a secondary coil 1742, and a switch 1743. The other end of the primary coil 1741 is connected to the negative input (V_{IN-}) of the voltage control converter 170 via the switch 1743. One end of the secondary coil 1742 is connected to one end of the capacitor 175 and the positive output (V_{OUT+}) of the voltage control converter 170. The other end of the secondary coil 1742 is connected to the other end of the capacitor 175 and the negative output (V_{OUT-}) of the voltage control converter 170.

A driver 1744 is connected to the switch 1743. The driver 1744 opens and closes the switch 1743. When the switch 1743 is closed, that is, when the other end of the primary coil 1741 and the negative input (V_{IN-}) are in a conductive state, the other end of the primary coil 1741 is connected to the negative input (V_{IN-}) of the voltage control converter 170, and DC power from the voltage control converter 170 is supplied to the constant voltage controller 180. On the other hand, when the switch 1743 is open, that is, when the other end of the primary coil 1741 and the negative input (V_{IN-}) are in a non-conductive state, the connection between the other end of the primary coil 1741 and the negative input (V_{IN-}) of the voltage control converter 170 is cut off, and the supply of DC power from the voltage control converter 170 to the constant voltage controller 180 is interrupted.

The voltage control converter 170 may further include a voltage detector 176v and a current detector 176i. The voltage detector 176v detects a voltage value between both ends of the secondary coil 1742 or a voltage value between the positive output and the negative output of the voltage control converter 170. The current detector 176i measures a current value between the other end of the secondary coil 1742 and the negative output of the voltage control converter 170. The voltage value detected by the voltage detector 176v and the current value detected by the current detector 176i are notified to the controller 172. The controller 172 may be the same as or different from at least one of the controller 122 and the controller 152.

The controller 172 controls the driver 1744 to cut off the supply of DC power from the voltage control converter 170 to the constant voltage controller 180 when the voltage value detected by the voltage detector 176v is equal to or greater than a threshold value. The voltage value between the positive output and the negative output of the voltage control converter 170 is the sum of the output voltage value of the voltage control converter 170 and the line-to-line potential difference due to normal mode noise. In this embodiment, damage to the load of the voltage control converter 170 due to overvoltage caused by the line-to-line potential difference due to normal mode noise can be suppressed.

### Constant Voltage Controller

Reference is made to FIGS. 25 and 26. FIGS. 25 and 26 are diagrams illustrating a constant voltage controller according to some example embodiments. The constant voltage controller 180 is connected between the energy storage 160 and at least one power consuming member 240, and is configured to control the application of a voltage (application of a DC voltage) to the at least one power consuming member 240 and the stopping thereof.

The constant voltage controller 180 includes a controller 182 and at least one switch 183. A positive input (V_{IN+}) of the constant voltage controller 180 is connected to the power consuming member 240 via the switch 183. A negative input (V_{IN-}) of the constant voltage controller 180 is connected to the power consuming member 240. The switch 183 is controlled by the controller 182. When the switch 183 is closed, a DC voltage from the constant voltage controller 180 is applied to the power consuming member 240. When the switch 183 is open, the application of the DC voltage from the constant voltage controller 180 to the power consuming member 240 is stopped. The controller 182 may be the same as or different from at least one of the controller 122, the controller 152, and the controller 172.

In the embodiment illustrated in FIGS. 25 and 26, the plasma processing apparatus includes a plurality of power consuming members 240. The constant voltage controller 180 includes a controller 182 and a plurality of switches 183. A positive input (V_{IN+}) of the constant voltage controller 180 is connected to the plurality of power consuming members 240 via the plurality of switches 183. A negative input (V_{IN-}) of the constant voltage controller 180 is connected to the plurality of power consuming members 240.

In the embodiment illustrated in FIGS. 25 and 26, the plurality of power consuming members 240 may include a plurality of heaters (resistance heating elements). The plurality of heaters may be provided in the substrate support 11. In the embodiment illustrated in FIG. 25, a plurality of resistors 260 are disposed in the vicinity of each of the plurality of heaters. Each of the plurality of resistors 260 has a resistance value that changes with temperature. Each of the plurality of resistors 260 is, for example, a thermistor. Each of the plurality of resistors 260 is connected in series with a reference resistor (not illustrated). The constant voltage controller 180 includes a plurality of measurement devices 184. Each of the plurality of measurement devices 184 applies a reference voltage to a series connection of the corresponding one of the plurality of resistors 260 and the reference resistor, and detects a voltage value across the resistor. Each of the plurality of measurement devices 184 notifies the controller 182 of the detected voltage value. The controller 182 identifies the temperature of the region in which the corresponding one of the plurality of heaters is disposed from the notified voltage value, and controls the application of the DC voltage to the corresponding heater so as to bring the temperature of the region close to a target temperature. Optical fiber thermometers may be disposed instead of the plurality of resistors 260. In this case, since wiring between the plurality of resistors 260 and the plurality of measurement devices 184 becomes unnecessary, the influence of radio frequency conducted noise on the power consuming member 240 can be eliminated.

In the embodiment illustrated in FIG. 26, the constant voltage controller 180 includes a voltage detector 185v and a plurality of current detectors 185i. The voltage detector 185v detects a voltage value applied to each of the plurality of heaters. Each of the plurality of current detectors 185i measures a value of current, that is, a current value, supplied to the corresponding one of the plurality of heaters. Each of the plurality of measurement devices 184 identifies the resistance value of the corresponding one of the plurality of heaters from the current value detected by the corresponding one of the plurality of current detectors 185i and the voltage value detected by the voltage detector 185v. The controller 182 identifies the temperature of each of a plurality of regions in which the plurality of heaters are respectively disposed from the detected resistance value of each of the plurality of heaters. The controller 182 controls the application of the DC voltage to each of the plurality of heaters so as to bring the temperature of each of the plurality of regions close to a target temperature.

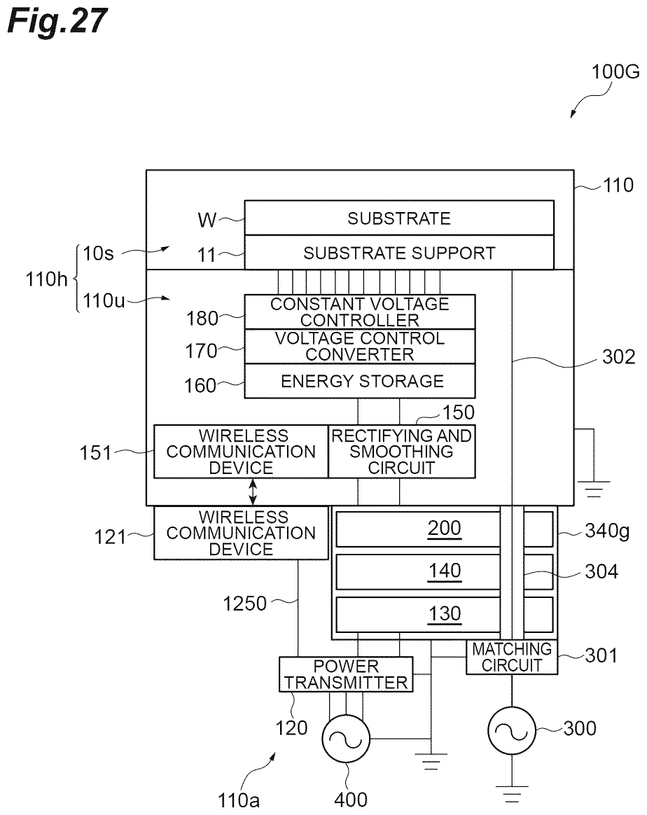

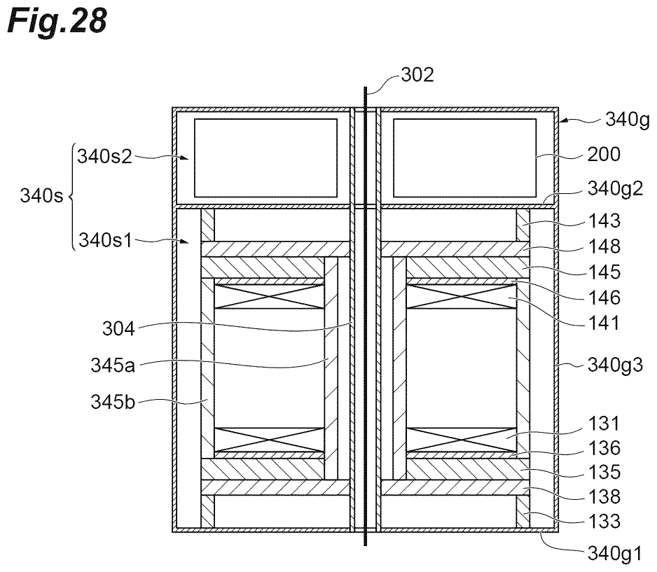

Hereinafter, a plasma processing apparatus according to yet another example embodiment will be described with reference to FIGS. 27 and 28. FIG. 27 is a diagram illustrating a plasma processing apparatus according to yet another example embodiment. FIG. 28 is a diagram illustrating a transmitting coil module and a receiving coil module in a plasma processing apparatus according to yet another example embodiment. Hereinafter, the plasma processing apparatus 100G illustrated in FIG. 27 will be described from the perspective of its differences from the plasma processing apparatus 100E.

As described above, the space 110h includes the space inside the chamber 10 (plasma processing space 10s) and a space 110u that is a non-reduced-pressure space. The rectifying and smoothing circuit 150, the energy storage 160, the voltage control converter 170, and the constant voltage controller 180 are disposed in the space 110u.

The plasma processing apparatus 100G further includes a metal housing 340g. The metal housing 340g is disposed in the space 110a. The metal housing 340g is grounded. As illustrated in FIG. 28, the metal housing 340g defines a shielded space 340s and accommodates the transmitting coil 131 and the receiving coil 141 in the shielded space 340s. The metal housing 340g may further accommodate the RF filter 200 in the shielded space 340s. The shielded space 340s may include a space 340s1 and a space 340s2. The transmitting coil 131 and the receiving coil 141 are accommodated in the space 340s1. The space 340s2 is located above the space 340s1. The RF filter 200 is accommodated in the space 340s2.

The metal housing 340g includes a first back wall 340g1, a second back wall 340g2, and a side wall 340g3. The first back wall 340g1 has a substantially flat plate shape and extends on the back side of the transmitting coil 131 relative to the receiving coil 141. The second back wall 340g2 has a substantially flat plate shape and extends on the back side of the receiving coil 141 relative to the transmitting coil 131. The side wall 340g3 has a tubular shape and defines the space 340s1 together with the first back wall 340g1 and the second back wall 340g2. The side wall 340g3 surrounds the outer periphery of the transmitting coil 131 and the outer periphery of the receiving coil 141.

In the shielded space 340s and between the first back wall 340g1 and the transmitting coil 131, a spacer 133, a base plate 138, a back ferrite member 135, and a thermal conductive sheet 136 are disposed in this order. The spacer 133 is interposed between the first back wall 340g1 and the base plate 138 and supports the base plate 138. The base plate 138 is, for example, a glass epoxy substrate. The back ferrite member 135 extends between the base plate 138 and the transmitting coil 131. That is, the back ferrite member 135 is disposed on the back side of the transmitting coil 131. The thermal conductive sheet 136 extends between the transmitting coil 131 and the back ferrite member 135.

Further, in the shielded space 340s and between the second back wall 340g2 and the receiving coil 141, a spacer 143, a base plate 148, a back ferrite member 145, and a thermal conductive sheet 146 are disposed in this order. The spacer 143 is interposed between the second back wall 340g2 and the base plate 148 and supports the base plate 148. The base plate 148 is, for example, a glass epoxy substrate. The back ferrite member 145 extends between the base plate 148 and the receiving coil 141. That is, the back ferrite member 145 is disposed on the back side of the receiving coil 141. The thermal conductive sheet 146 is interposed between the receiving coil 141 and the back ferrite member 145.

The plasma processing apparatus 100G may further include an inner ferrite member 345a and an outer ferrite member 345b. The inner ferrite member 345a has a substantially tubular shape. The inner ferrite member 345a extends through the inside of the transmitting coil 131 and the inside of the receiving coil 141. The inner ferrite member 345a may extend from the back ferrite member 135 to the back ferrite member 145. The outer ferrite member 345b has a substantially tubular shape. The outer ferrite member 345b extends through the outer side of the transmitting coil 131 and the outer side of the receiving coil 141 so as to surround the transmitting coil 131 and the receiving coil 141. The outer ferrite member 345b may extend from the back ferrite member 135 to the back ferrite member 145.

The radio frequency power supply 300 may be electrically coupled to the substrate support 11 via a radio frequency power supply line 302, similarly to the various example embodiments described above. The radio frequency power supply line 302 extends from the substrate support 11 through the space 110u to the space 110a and is connected to the matching circuit 301, and is electrically coupled to the radio frequency power supply 300 via the matching circuit 301. In the space 110a, the radio frequency power supply line 302 passes through a ground pipe 304 and is surrounded by the ground pipe 304. The ground pipe 304 is a tubular conductor and is electrically grounded. The ground pipe 304 may be electrically connected to the ground frame 110. The ground pipe 304 may extend from the ground frame 110 to the matching circuit 301.

In the plasma processing apparatus 100G, the ground pipe 304 extends through the inside of the transmitting coil 131 and the inside of the receiving coil 141. The ground pipe 304 may pass through the inner ferrite member 345a, while being spaced apart from the inner ferrite member 345a. The ground pipe 304 and the inner ferrite member 345a may be separated from each other by an insulation distance or more.

In the plasma processing apparatus 100G, the radio frequency power supply line 302 and the ground pipe 304 extend through the inside of the transmitting coil 131 and the inside of the receiving coil 141 in the space 110a. Therefore, it is possible to reduce the space for the radio frequency power supply line 302 outside the chamber 10. Hence, according to the plasma processing apparatus 100G, a high degree of freedom in the layout of other components in the space 110a is obtained. In addition, since the space available in the space 110a is large, it is possible to increase the size of each of the transmitting coil 131 and the receiving coil 141. As a result, transmission of high power becomes possible.

In addition, the back ferrite member 135, the back ferrite member 145, the inner ferrite member 345a, and the outer ferrite member 345b suppress leakage of magnetic flux. Therefore, high power transmission efficiency between the transmitting coil 131 and the receiving coil 141 is obtained.

The back ferrite member 135, the back ferrite member 145, the inner ferrite member 345a, and the outer ferrite member 345b may be formed of a manganese-zinc ferrite, a nickel-zinc ferrite, or a nanocrystalline soft magnetic material. In this case, when the transmission frequency is 1 MHz or less, a high magnetic flux confinement effect at the transmission frequency is obtained due to high magnetic permeability, and it is possible to efficiently convert conducted noise into heat.

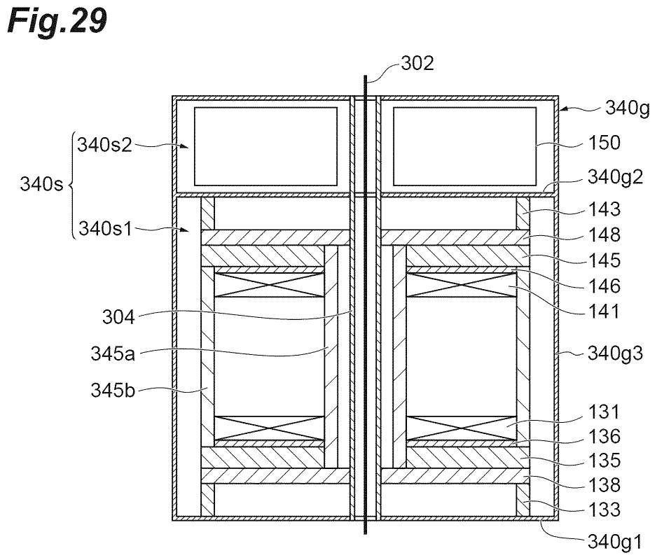

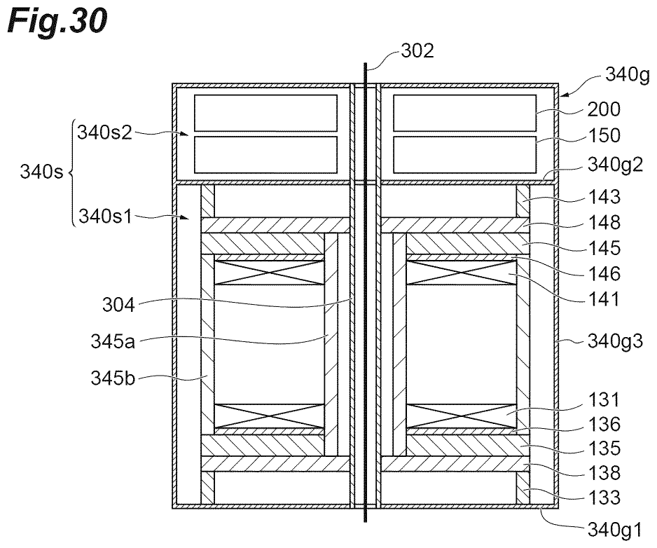

Hereinafter, reference is made to FIGS. 29 and 30. Each of FIGS. 29 and 30 is a diagram illustrating a transmitting coil module and a receiving coil module in a plasma processing apparatus according to yet another example embodiment. The configuration illustrated in each of FIGS. 29 and 30 may be employed in the plasma processing apparatus 100G in place of the configuration illustrated in FIG. 28. As illustrated in FIG. 29, the rectifying and smoothing circuit 150 may be disposed in the space 340s2 in place of the RF filter 200. As illustrated in FIG. 30, both the RF filter 200 and the rectifying and smoothing circuit 150 may be disposed in the space 340s2. In the configuration illustrated in FIG. 30, the rectifying and smoothing circuit 150 is connected to the energy storage 160 via the RF filter 200.

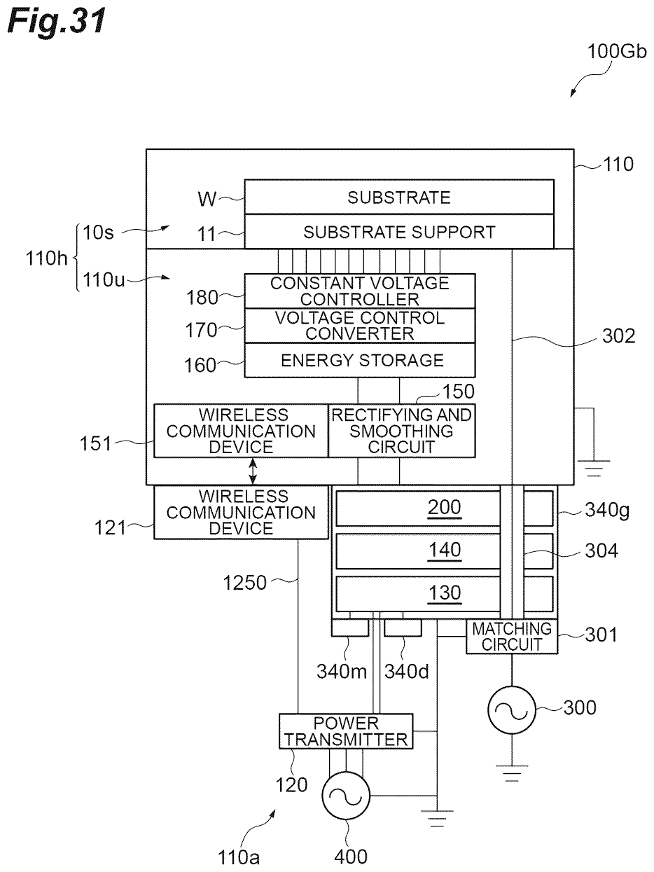

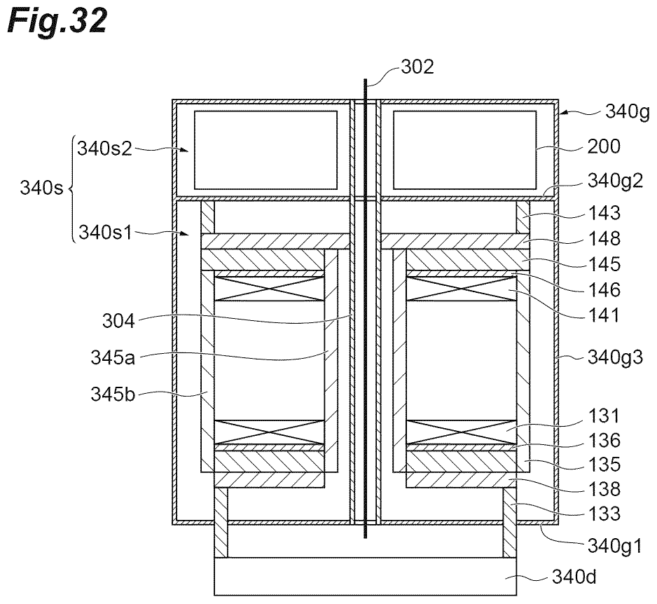

Hereinafter, a plasma processing apparatus according to yet another example embodiment will be described with reference to FIGS. 31 and 32. FIG. 31 is a diagram illustrating a plasma processing apparatus according to yet another example embodiment. FIG. 32 is a diagram illustrating a transmitting coil module and a receiving coil module in a plasma processing apparatus according to yet another example embodiment. Hereinafter, the plasma processing apparatus 100Gb illustrated in FIGS. 31 and 32 will be described from the perspective of its differences from the plasma processing apparatus 100G.

The plasma processing apparatus 100Gb further includes a drive system 340d and a sensor 340m. The drive system 340d is configured to move the transmitting coil 131 to change the distance between the transmitting coil 131 and the receiving coil 141, that is, the length of the gap between the transmitting coil 131 and the receiving coil 141.

In the plasma processing apparatus 100Gb, the drive system 340d may be configured to move a transmitting coil assembly. The transmitting coil assembly includes the transmitting coil 131, the base plate 138, the back ferrite member 135, and the thermal conductive sheet 136.

The drive system 340d includes at least one actuator. The at least one actuator is composed of a hydraulic or pneumatic cylinder, a motor, a piezoelectric element, or the like. The drive system 340d may include a plurality of actuators. The drive system 340d may detect the parallelism between the transmitting coil 131 and the receiving coil 141 using the sensor 340m and control the at least one actuator so as to keep the transmitting coil 131 and the receiving coil 141 parallel to each other according to the detection result of the sensor 340m.

In the configuration illustrated in FIG. 32, the RF filter 200 is disposed in the space 340s2; however, in the plasma processing apparatus 100Gb as well, the rectifying and smoothing circuit 150 may be disposed in the space 340s2 in place of the RF filter 200, similarly to the configuration illustrated in FIG. 29. Alternatively, in the plasma processing apparatus 100Gb as well, both the rectifying and smoothing circuit 150 and the RF filter 200 may be disposed in the space 340s2, similarly to the configuration illustrated in FIG. 30.

According to the plasma processing apparatus 100Gb described above, since the distance between the transmitting coil 131 and the receiving coil 141 can be changed, the power transmission efficiency between the transmitting coil 131 and the receiving coil 141 can be improved, and it is possible to suppress radio frequency noise (or conducted noise) from the receiving coil 141 to the transmitting coil 131.

The plasma processing apparatus 100G and the plasma processing apparatus 100Gb need not include one of the inner ferrite member 345a and the outer ferrite member 345b. Further, the plasma processing apparatus 100G and the plasma processing apparatus 100Gb need not include either the inner ferrite member 345a or the outer ferrite member 345b. Further, the plasma processing apparatus 100G and the plasma processing apparatus 100Gb need not include one or both of the back ferrite member 135 and the back ferrite member 145.

Although various example embodiments have been described above, various additions, omissions, substitutions, and changes may be made without being limited to the example embodiments described above. It is also possible to combine elements in different embodiments to form other embodiments.

Here, various example embodiments included in the present disclosure are described in [E1] to [E10] below.

### [E1]

A plasma processing apparatus including:
a plasma processing chamber;
a substrate support in the plasma processing chamber;
a load in the plasma processing chamber or in the substrate support;
a transmitting coil;
a receiving coil configured to receive power from the transmitting coil by electromagnetic induction coupling;
a rectifying and smoothing circuit configured to convert power from the receiving coil into DC power;
an energy storage electrically connected between the rectifying and smoothing circuit and the load;
a radio frequency power supply line;
a radio frequency power supply configured to generate radio frequency power to be supplied into the plasma processing chamber via the radio frequency power supply line; and
a ground pipe that extends through an inside of the receiving coil and an inside of the transmitting coil and is configured to electrically couple to ground, the radio frequency power supply line extending through the ground pipe outside the plasma processing chamber.

### [E2]

The plasma processing apparatus according to E1, further including:
an inner ferrite tube having a tubular shape and extending through the inside of the receiving coil and the inside of the transmitting coil,
wherein the ground pipe passes through the inner ferrite tube and is spaced apart from the inner ferrite tube.

### [E3]

The plasma processing apparatus according to E1 or E2, further including:
an outer ferrite tube extending through an outer side of the receiving coil and the outer side of the transmitting coil to surround the receiving coil and the transmitting coil.

### [E4]

The plasma processing apparatus according to any one of E1 to E3, further including:
a ground frame configured to couple to ground and which surrounds the substrate support together with the plasma processing chamber,
wherein the ground pipe is electrically connected to the ground frame.

### [E5]

The plasma processing apparatus according to E4, further including:
a matching circuit connected between the radio frequency power supply and the radio frequency power supply line,
wherein the ground pipe extends between the ground frame and the matching circuit.

### [E6]

The plasma processing apparatus according to any one of E1 to E5, further including:
a metal housing surrounding the transmitting coil and the receiving coil.

### [E7]

The plasma processing apparatus according to E6, further including an RF filter configured to suppress propagation of the radio frequency power and connected between the receiving coil and the rectifying and smoothing circuit,
wherein the RF filter is in the metal housing.

### [E8]

The plasma processing apparatus according to E6, wherein the rectifying and smoothing circuit is in the metal housing.

### [E9]

The plasma processing apparatus according to E6, further including an RF filter configured to suppress propagation of the radio frequency power and connected between the rectifying and smoothing circuit and the energy storage,
wherein the rectifying and smoothing circuit and the RF filter are in the metal housing.

### [E10]

The plasma processing apparatus according to any one of E1 to E9, further including a drive system configured to move the transmitting coil to change a distance between the receiving coil and the transmitting coil.

From the above description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit are indicated by the appended claims.

What is claimed is:

1. A plasma processing apparatus comprising:
a plasma processing chamber;
a substrate support in the plasma processing chamber;
a load in the plasma processing chamber or in the substrate support;
a transmitting coil;
a receiving coil configured to receive power from the transmitting coil by electromagnetic induction coupling;
a rectifying and smoothing circuit configured to convert power from the receiving coil into DC power;
an energy storage electrically connected between the rectifying and smoothing circuit and the load;
a radio frequency power supply line;
a radio frequency power supply configured to generate radio frequency power to be supplied into the plasma processing chamber via the radio frequency power supply line; and
a ground pipe that extends through an inside of the receiving coil and an inside of the transmitting coil and is configured to electrically couple to ground, the radio frequency power supply line extending through the ground pipe outside the plasma processing chamber.

2. The plasma processing apparatus according to claim 1, further comprising:
an inner ferrite tube extending through the inside of the receiving coil and the inside of the transmitting coil,
wherein the ground pipe passes through the inner ferrite tube and is spaced apart from the inner ferrite tube.

3. The plasma processing apparatus according to claim 1, further comprising:
an outer ferrite tube extending through an outer side of the receiving coil and the outer side of the transmitting coil to surround the receiving coil and the transmitting coil.

4. The plasma processing apparatus according to claim 1, further comprising:
a ground frame configured to couple to ground and which surrounds the substrate support together with the plasma processing chamber,
wherein the ground pipe is electrically connected to the ground frame.

5. The plasma processing apparatus according to claim 4, further comprising:
a matching circuit connected between the radio frequency power supply and the radio frequency power supply line,
wherein the ground pipe extends between the ground frame and the matching circuit.

6. The plasma processing apparatus according to claim 1, further comprising:
a metal housing surrounding the transmitting coil and the receiving coil.

7. The plasma processing apparatus according to claim 6, further comprising:
an RF filter configured to suppress propagation of the radio frequency power and connected between the receiving coil and the rectifying and smoothing circuit,
wherein the RF filter is in the metal housing.

8. The plasma processing apparatus according to claim 6, wherein
the rectifying and smoothing circuit is in the metal housing.

9. The plasma processing apparatus according to claim 6, further comprising:
an RF filter configured to suppress propagation of the radio frequency power and connected between the rectifying and smoothing circuit and the energy storage,
wherein the rectifying and smoothing circuit and the RF filter are in the metal housing.

10. The plasma processing apparatus according to claim 1, further comprising:
a drive system configured to move the transmitting coil to change a distance between the receiving coil and the transmitting coil.
